(19) United States
(12) Patent Application Publication
(10) Pub. No.: US 2026/0262541 A1
(43) Pub. Date: Sep. 3, 2026

(54) POWER MODULES WITH HIGH CURRENT DENSITY

(71) Applicant: Analog Devices, Inc., Wilmington, MA (US)

(72) Inventor: Vikas Paduvalli, San Jose, CA (US)

(21) Appl. No.: 19/067,405

(22) Filed: Feb. 28, 2025

(51) Int. Cl. H01L 25/18; H01L 23/373; H01L 23/538; H01L 25/00; H10D 1/20

(52) U.S. Cl. CPC H10W 90/00; H10D 1/20; H10W 40/258; H10W 70/611; H10W 90/401

(57) ABSTRACT

Power modules with enhanced current density are disclosed herein. In certain embodiments, a power module includes a first circuit board, a first semiconductor die attached to a first side of the first circuit board, and an inductor component attached to a second side of the first circuit board opposite the first side. The inductor component includes a dielectric body having a cavity facing the first circuit board. The power module further includes a second semiconductor die attached to the second side of the first circuit board in the cavity of the inductor component.

### FIELD OF THE DISCLOSURE

Embodiments of the invention relate to electronic systems, and more particularly, to power modules for providing power regulation.

### BACKGROUND

A power module can include one or more switching regulators that operate in combination with one or more inductors to provide power regulation. For example, the switching regulator can employ switches (for instance, power transistors) coupled in series and/or parallel with an output terminal that provides an output voltage to a load through an inductor. Additionally, a controller turns the switches ON and OFF to control delivery of current pulses to the output terminal through the inductor, which converts the switched pulses into a steady load current.

A power module can include a semiconductor die on which metal-oxide-semiconductor field-effect transistors (MOSFETs) and a driver are formed. Such a semiconductor die is referred to as a driver and MOSFET (DrMOS) die or integrated circuit (IC).

### SUMMARY OF THE DISCLOSURE

Power modules with enhanced current density are disclosed herein. In certain embodiments, a power module includes a first circuit board, a first semiconductor die attached to a first side of the first circuit board, and an inductor component attached to a second side of the first circuit board opposite the first side. The inductor component includes a dielectric body having a cavity facing the first circuit board. The power module further includes a second semiconductor die attached to the second side of the first circuit board in the cavity of the inductor component. By implementing the power module in this manner, higher current density (for instance, double the current density) is achieved relative to a power module in which a semiconductor die is included only on top of the circuit board. Furthermore, such a configuration provides more semiconductor dies for a given area thus providing less loss per die and higher overall efficiency.

In one aspect, a power module includes a first circuit board having a first side and a second side opposite the first side, a first semiconductor die attached to the first side of the first circuit board, and an inductor component attached to the second side of the first circuit board. The inductor component has a dielectric body and a first cavity in the dielectric body facing the second side of the first circuit board. The power module further includes a second semiconductor die attached to the second side of the first circuit board in the cavity of the dielectric body.

In another aspect, a power regulation system includes a customer board and a power module attached to the customer board. The power module includes a first circuit board having a first side and a second side opposite the first side, a first semiconductor die attached to the first side of the first circuit board, and an inductor component attached to the second side of the first circuit board. The inductor component has a dielectric body and a first cavity in the dielectric body facing the second side of the first circuit board. The power module further includes a second semiconductor die attached to the second side of the first circuit board in the cavity of the dielectric body.

In another aspect, a method of assembling a power module is disclosed. The method includes attaching a first semiconductor die to a first side of a first circuit board, attaching a second semiconductor die to a second side of the first circuit board opposite the first side, and attaching an inductor component attached to the second side of the first circuit board. The inductor component has a dielectric body and a first cavity in the dielectric body facing the second side of the first circuit board, and the second semiconductor die is positioned in the cavity of the dielectric body.

### BRIEF DESCRIPTION OF THE DRAWINGS

FIG. 1A is a front perspective view of a power module according to one embodiment.

FIG. 1B is a cross-sectional view of the power module of FIG. 1A.

FIG. 1C is a cross-sectional view of the power module of FIG. 1A attached to a customer circuit board and a cold plate/heat sink.

FIG. 2A is a front perspective view of another embodiment of an inductor component for the power module of FIG. 1A.

FIG. 2B is a plan view of the inductor component of FIG. 2A.

FIG. 3 is a cross-section of another embodiment of an inductor component.

FIG. 4A is one embodiment of a cooling configuration for the power module of FIG. 1A.

FIG. 4B is a graph of simulated thermal performance for the cooling configuration of FIG. 2A.

FIG. 4C is another embodiment of a cooling configuration for the power module of FIG. 1A.

FIG. 4D is a graph of simulated thermal performance for the cooling configuration of FIG. 4C.

FIG. 4E is another embodiment of a cooling configuration for the power module of FIG. 1A.

FIG. 4F is a graph of simulated thermal performance for the cooling configuration of FIG. 4E.

FIG. 5 is a front perspective view of a power module according to another embodiment.

FIG. 6 is a front perspective view of a power module according to another embodiment.

FIG. 7 is a circuit diagram of a power module according to one embodiment.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Existing packaging techniques for power modules pose a challenge for power density. For example, current density requirements for power modules have been steadily increasing each year, while achievable current density heavily depends on available cooling techniques. Furthermore, it is difficult to remove heat from silicon chips used for power regulation, and silicon technology is still catching up with increasing demand for higher and higher current densities.

Power modules with enhanced current density are disclosed herein. In certain embodiments, a power module includes a first circuit board, a first semiconductor die attached to a first side of the first circuit board, and an inductor component attached to a second side of the first circuit board opposite the first side. The inductor component includes a dielectric body having a cavity facing the first circuit board. The power module further includes a second semiconductor die attached to the second side of the first circuit board in the cavity of the inductor component.

By implementing the power module in this manner, higher current density (for instance, double the current density) is achieved relative to a power module in which a semiconductor die is included only on top of the circuit board. Furthermore, such a configuration provides more semiconductor dies for a given area thus providing less loss per die and higher overall efficiency.

Accordingly, the second semiconductor die is positioned within the cavity of the dielectric body of the inductor component. In certain implementations, the cavity has a height of less than 1 mm, thereby providing little to no impact on the performance of the inductor component. The cavity can be an air cavity or filled with any suitable dielectric.

Additional semiconductor dies can be included on the first and second sides of the first circuit board as needed for a given power regulation application. In one example, a third semiconductor die is also attached to the first side of the first circuit board, and a fourth semiconductor die is also attached to the second side of the first circuit board in the cavity of the dielectric body.

The semiconductor die(s) on the first side of the first circuit board are referred to herein as top semiconductor die(s), while the semiconductor die(s) on the second side of the first circuit board in the cavity of the dielectric body are referred to herein as bottom semiconductor die(s).

The inductor component can include one or more inductors (for instance, copper windings) that extend through the dielectric body (for example, a ferrite core). The inductors can be electromagnetically coupled or electromagnetically uncoupled from one another based on implementation. For example, for applications in which electromagnetically coupling is desired, the inductors can be implemented with a particular value of mutual inductance to achieve a strength of magnetic coupling desired for a given application.

The number of inductors included in the inductor component can correspond to a desired number of phases for power regulation. In a first example, one inductor is included to provide a single-phase power module. In another example, two inductors are included to provide a two-phase (2-phase) power module. In yet another example, four inductors are included to provide a four-phase (4-phase) power module.

In certain implementations, each inductor of the inductor component is electrically connected to a corresponding output of a semiconductor die. For example, each semiconductor die can correspond to a DrMOS die that operates to regulate a current through one or more inductors.

The bottom semiconductor die(s) can be cooled through the top semiconductor die(s). For example, in certain implementations, a cold plate and/or heat sink is placed over the top semiconductor die(s), and heat is pulled from the bottom semiconductor die(s) to the top semiconductor die(s) through the first circuit board.

For example, in certain implementations, metallization (for instance, vias) in the first circuit board thermally connects metal pads on the bottom semiconductor die(s) to metal pads on the top semiconductor die(s), thus providing a thermal pathway for heat transfer. Such metallization can also provide electrical connections (for instance, ground or input power supply voltage) and thus such metallization can be multi-functional.

Accordingly, excellent thermal performance is achieved by providing a thermal pathway for heat to transfer from the bottom semiconductor die(s) to the top semiconductor die(s) through the first circuit board.

In addition to including semiconductor dies (for instance, DrMOS dies), additional components can be attached to the first circuit board using surface mount technology (SMT). In one example, surface mount components such as capacitors are included alongside the top semiconductor die(s) and/or bottom semiconductor die(s).

In certain implementations, a second circuit board is attached to the inductor component opposite the first circuit board. The second circuit board in turn can connect to a customer board.

The inductors formed through the dielectric body of the inductor component can be electrically connected to the first circuit board and the second circuit board as desired. In one example, each inductor of the inductor component includes a first terminal electrically connected to the first circuit board and a second terminal electrically connected to the second circuit board. Thus, the inductors of the inductor component can be electrically connected between the first circuit board and the second circuit board.

In certain implementations, one or more additional cavities are formed in the dielectric body between the inductor component and the second circuit board. The additional cavities can provide area for SMT components, such as capacitors.

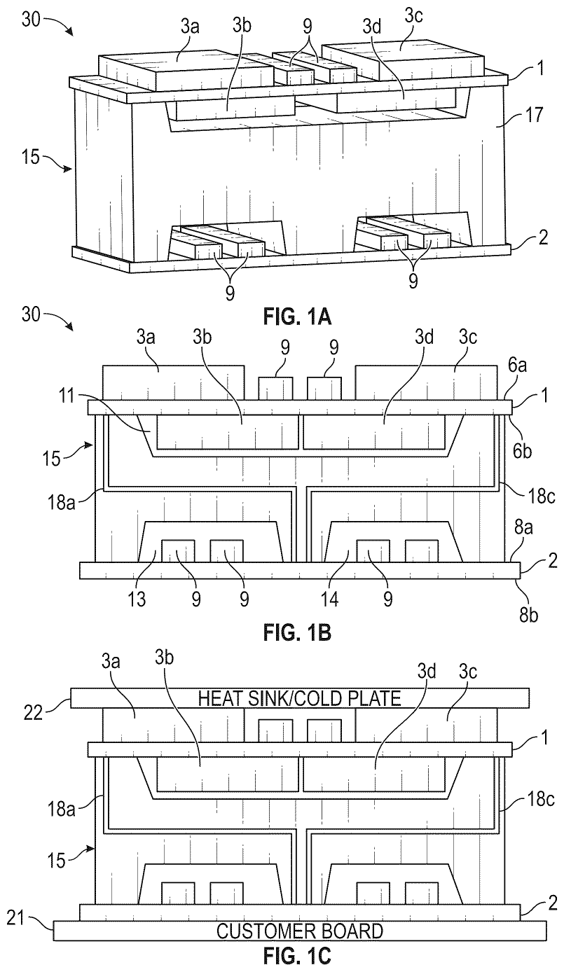

FIG. 1A is a front perspective view of a power module 30 according to one embodiment. FIG. 1B is a cross-sectional view of the power module 30 of FIG. 1A. FIG. 1C depicts the power module 30 of FIG. 1A attached to a customer circuit board 21 and a cold plate/heat sink 22.

The power module 30 includes a first or top circuit board 1, a second or bottom circuit board 2, a first semiconductor die 3a, a second semiconductor die 3b, a third semiconductor die 3c, a fourth semiconductor die 3d, surface mount components 9, and an inductor component 15.

With general reference to FIGS. 1A to 1C, the power module 30 includes semiconductor dies attached to both sides of the top circuit board 1. For example, the first semiconductor die 3a and the third semiconductor die 3c correspond to top semiconductor dies attached to a first side 6a of the top circuit board 1, while the second semiconductor die 3b and the fourth semiconductor die 3d correspond to bottom semiconductor dies attached to a second side 6b of the top circuit board 1.

In the illustrated embodiment, the inductor component 15 includes a dielectric body 17 in which a cavity 11 has been formed. The dielectric body 17 is attached to the second side 6b of the top circuit board 1 and to a first side 8a of the bottom circuit board 2. Additionally, the bottom semiconductor dies 3b/3d are positioned within the cavity 11 of the dielectric body 17.

The power module 30 of FIGS. 1A-1C achieves higher current density (for instance, double the current density) relative to a power module in which semiconductor dies are included only on top of the top circuit board 1. Furthermore, such a configuration provides more semiconductor dies for a given area thus providing less loss per die and higher overall efficiency.

Thus, the bottom semiconductor dies 3b/3d are positioned within the cavity 11 of the dielectric body 17 of the inductor component 15. In certain implementations, the cavity 11 has a height of less than 1 mm, thereby providing little to no impact on the performance of the inductor component 15. The cavity 11 can be an air cavity or filled with any suitable dielectric.

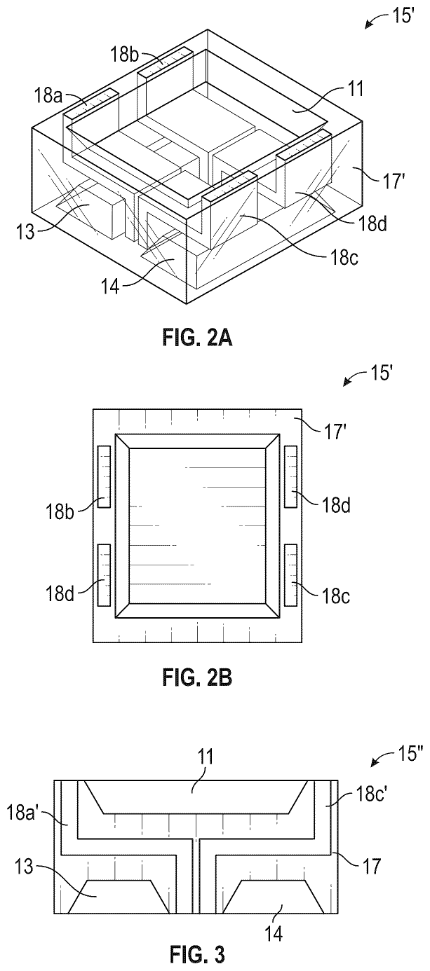

The inductor component 15 of the power module 30 includes four inductors (for instance, copper windings) that extend through the dielectric body 17 (for example, a ferrite core). In this embodiment, the inductor component 15 includes a first inductor 18a, a second inductor 18b, a third inductor 18c, and a fourth inductor 18d, which include a metallization structure as depicted in FIGS. 2A and 2B.

The number of inductors included in the inductor component 15 can correspond to a desired number of phases for power regulation. For example, the power module 30 of FIGS. 1A-1C includes four inductors to provide four-phase (4-phase) power regulation.

Each of the inductors is electrically connected to a corresponding output of the semiconductor dies 3a-3d, respectively. For example, each of the semiconductor dies 3a-3d can correspond to a DrMOS die that operates to regulate a current through a corresponding one of the four inductors.

Accordingly, each of the inductors of the inductor component 15 can include a first terminal electrically connected to the top circuit board 1 (and to a corresponding output of a semiconductor die through the metallization of the top circuit board 1) and a second terminal electrically connected to the bottom circuit board 2. The second side 8b of the bottom circuit board 2 connects to the customer circuit board 21, with the metallization of the bottom circuit board 2 serving to connect the inductors to the desired node or nodes of the customer board 21.

The top circuit board 1 and/or the bottom circuit board 2 can include various surface mount components 9 (for example, capacitors) attached as desired. In some implementations, the surface mount capacitors are included in one or more cavities of the dielectric body 17 of the inductor component 15. For example, the illustrated embodiment includes a second cavity 13 and a third cavity 14 on the dielectric body 17 facing the second bottom circuit board 2, and surface mount components 9 are included in each of the second cavity 13 and the third cavity 14.

In the illustrated embodiment, the bottom semiconductor dies 3b/3d can be cooled through the top semiconductor dies 3a/3c. For example, when the cold plate and/or the heat sink 22 is placed over the top semiconductor dies 3a/3c, heat is pulled from the bottom semiconductor dies 3b/3d to the top semiconductor dies 3a/3c through the top circuit board 1.

In certain implementations, metallization (for example, vias) in the top circuit board 1 thermally connect metal pads on the bottom semiconductor dies 3b/3d to metal pads on the top semiconductor dies 3a/3c, thus providing a thermal pathway for heat transfer. Such metallization can also provide electrical connections (for instance, ground or an input power supply voltage) and thus the metallization can be multi-functional.

Accordingly, excellent thermal performance is achieved by providing a thermal pathway for heat to transfer from the bottom semiconductor die(s) to the top semiconductor die(s) through the top circuit board 1.

FIG. 2A is a front perspective view of another embodiment of an inductor component 15′ for the power module of FIG. 1A. FIG. 2B is a plan view of the inductor component 15′ of FIG. 2A.

The inductor component 15′ includes four inductors (for instance, copper windings) that extend through the dielectric body 17′ (for example, a ferrite core). For instance, the inductor component 15′ includes a first inductor 18a, a second inductor 18b, a third inductor 18c, and a fourth inductor 18d.

Each of the inductors 18a-18d includes a first terminal at the top of the dielectric body 17′ and a second terminal at the bottom of the dielectric body 17′. Such a configuration of the inductors 18a-18d allows for each inductor to be electrically connected between a first circuit board (for example, the top circuit board 1 of FIGS. 1A-1C) and a second circuit board (for example, the bottom circuit board 2 of FIGS. 1A-1C).

The inductor component 15′ of FIGS. 2A-2B is similar to the inductor component 15 of FIGS. 1A-1C, except that the inductor component 15′ includes a dielectric body 17′ that laterally surrounds the cavity 11 on each side of the cavity 11. In contrast, FIGS. 1A-1C depict the dielectric body 17 of the inductor component 15 as being open on two of four sides. Likewise, the dielectric body 17′ of the inductor component 15′ laterally surrounds the cavity 13 and the cavity 14 in a similar manner.

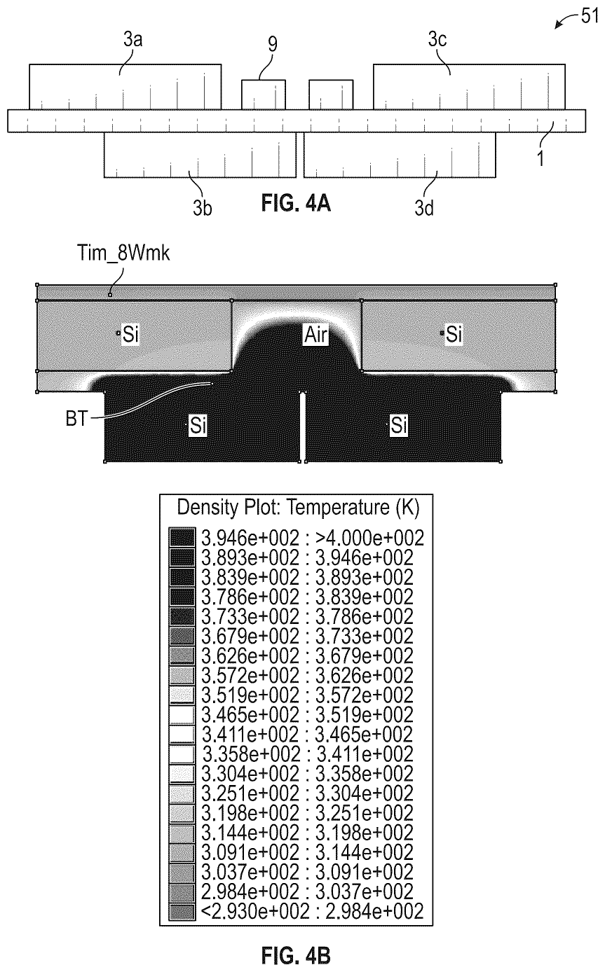

FIG. 3 is a cross-section of another embodiment of an inductor component 15′′. The inductor component 15′′ includes a dielectric body 17′ with four inductors (including inductor 18a′ and inductor 18c′) formed therethrough.

The inductor component 15′′ of FIG. 3 is similar to the inductor component 15′ of FIGS. 2A-2B, except that inductor component 15′′ of FIG. 3 includes inductors formed of thicker metal. The metal thickness and shape of an inductor can be chosen based on a variety of factors, including power handling, resistance, and/or other operational characteristics desired for a power module.

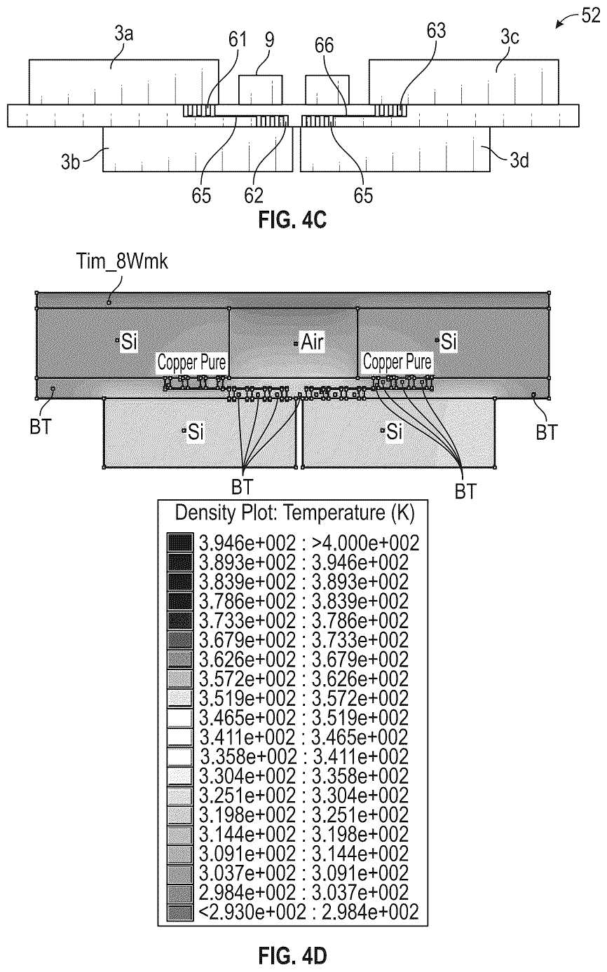

With general reference to FIGS. 4A to 4F, various examples of thermal performance configurations and simulations for cooling the bottom semiconductor dies 3b/3d of the power module 30 of FIG. 1A will now be described.

FIG. 4A is one embodiment of a cooling configuration 51 for the power module 30 of FIG. 1A. In this example, no metallization of the top circuit board 1 is used to connect metal pads on the bottom semiconductor dies 3b/3d to metal pads on the top semiconductor dies 3a/3c.

FIG. 4B is a graph of simulated thermal performance for the cooling configuration 51 of FIG. 4A.

As shown in FIG. 4B, heat builds up in the bottom semiconductor dies 3b/3d during operation of the power module 30.

FIG. 4C is another embodiment of a cooling configuration 52 for the power module 30 of FIG. 1A. In this example, metallization of the top circuit board 1 is used to connect metal pads on the bottom semiconductor dies 3b/3d to metal pads on the top semiconductor dies 3a/3c. For example, first vias 61 connect metal pads of the first semiconductor die 3a to a first conductor 65, while second vias 62 connect metal mads of the second semiconductor die 3b to the first conductor 65. Additionally, third vias 63 connect metal pads of the third semiconductor die 3d to a second conductor 66, while fourth vias 64 connect metal mads of the fourth semiconductor die 3d to the second conductor 66.

FIG. 4D is a graph of simulated thermal performance for the cooling configuration of FIG. 4C.

As shown in FIG. 4D, the metallization of the cooling configuration 52 of FIG. 4C reduces heat built up in the bottom semiconductor dies 3b/3d relative to the cooling configuration 51 of FIG. 4A.

FIG. 4E is another embodiment of a cooling configuration 53 for the power module 30 of FIG. 1A. In this example, metallization of the top circuit board 1 is used to directly connect metal pads on the bottom semiconductor dies 3b/3d to metal pads on the top semiconductor dies 3a/3c. For example, first vias 71 provide a direct vertical connection between the metal pads of the first semiconductor die 3a and the metal mads of the second semiconductor die 3b. Additionally, second vias 72 provide a direct vertical connection between the metal pads of the third semiconductor die 3c and the metal mads of the fourth semiconductor die 3d.

FIG. 4F is a graph of simulated thermal performance for the cooling configuration 53 of FIG. 4E.

As shown in FIG. 4F, the metallization of the cooling configuration 53 of FIG. 4E reduces heat built up in the bottom semiconductor dies 3b/3d relative to both the cooling configuration 51 of FIG. 4A and the cooling configuration 52 of FIG. 4C.

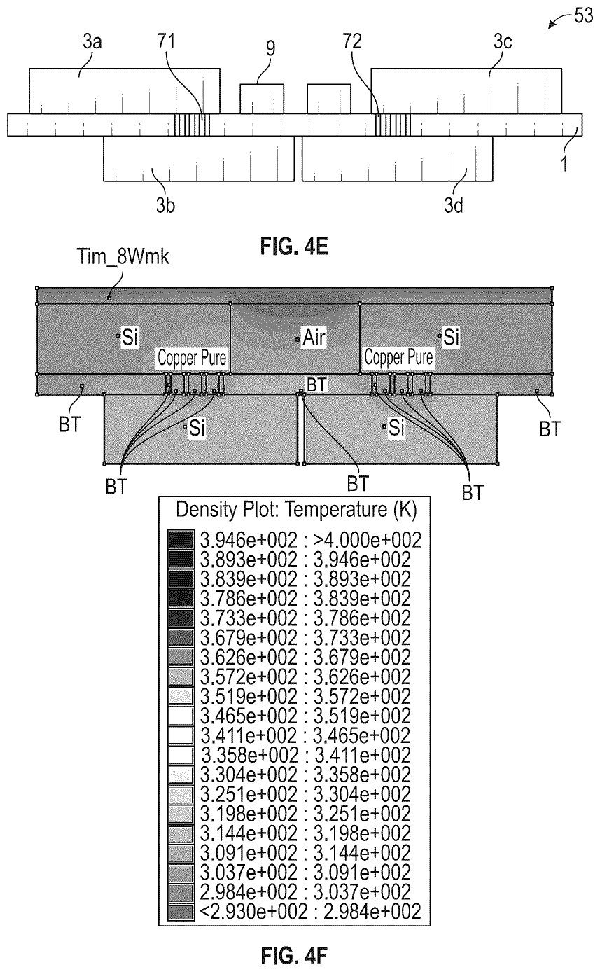

FIG. 5 is a front perspective view of a power module 80 according to another embodiment. The power module 80 includes a top circuit board 1, a bottom circuit board 2, an inductor component 85 including a dielectric body 87 and two inductors formed therein (for example, inductors 18a/18b shown in FIGS. 2A-2B), a first semiconductor die 83a attached to a first side of the top circuit board 1, and a second semiconductor die 83b attached to a second side of the top circuit board 1 in a recess 11 of the dielectric body 87.

The power module 80 of FIG. 5 is similar to the power module 30 of FIG. 1A, except the power module 80 of FIG. 5 includes half the semiconductor dies and half the inductors.

In this example, the power module 80 is a 2-phase power regulator. The power modules herein can be implemented to include any desired number of phases.

Although not shown in FIG. 5, various surface mount components can be included on the top circuit board 1 and/or the bottom circuit board 2.

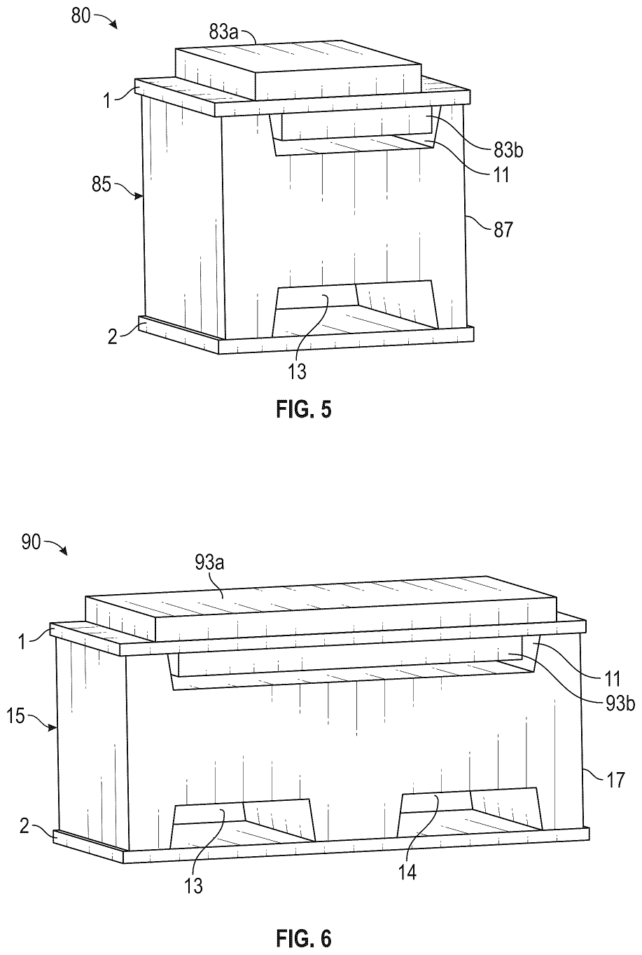

FIG. 6 is a front perspective view of a power module 90 according to another embodiment. The power module 90 includes a top circuit board 1, a bottom circuit board 2, an inductor component 15 including a dielectric body 17 and four inductors formed therein (for example, inductors 18a-18d shown in FIGS. 2A-2B), a first semiconductor die 93a attached to a first side of the top circuit board 1, and a second semiconductor die 93b attached to a second side of the top circuit board 1 in a recess 11 of the dielectric body 17.

The power module 90 of FIG. 6 is similar to the power module 30 of FIG. 1A, except each semiconductor die 93a/93b in the power module 90 provides regulation to two inductors. The power modules herein can be implemented to include semiconductor dies that provide regulation to any desired number of inductors.

Although not shown in FIG. 6, various surface mount components can be included on the top circuit board 1 and/or the bottom circuit board 2.

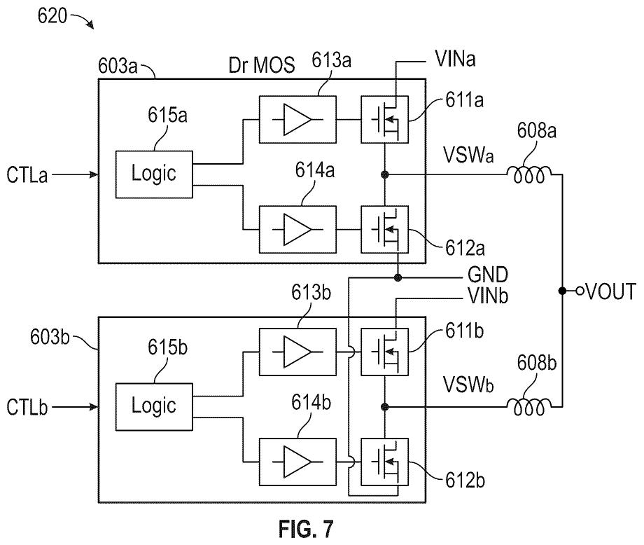

FIG. 7 is a circuit diagram of a power module 620 according to one embodiment. The power module 620 includes a first DrMOS die 603a that regulates a current through a first inductor 608a and a second DrMOS die 603b that regulates a current through a second inductor 608b. Although an example of a 2-phase power module is depicted, a power module can include more or fewer phases as needed for a particular application. For example, the depicted circuitry can be replicated to provide circuitry for a 4-phase power module. Furthermore, although an example in which one semiconductor die provides regulation to one inductor, the teachings herein are also application to semiconductor dies that provide regulation to two or more inductors. Thus, the number of semiconductor dies need not equal the number of inductors.

In the illustrated embodiment, the first DrMOS die 603a includes a first high side power MOSFET 611a, a first low side power MOSFET 612a, a first high side driver 613a, a first low side driver 614a, and a first driver logic circuit 615a. Additionally, the second DrMOS die 603b includes a second high side power MOSFET 611b, a second low side power MOSFET 612b, a second high side driver 613b, a second low side driver 614b, and a second driver logic circuit 615b.

Although one example of DrMOS dies is shown, DrMOS dies can be implemented in other ways. Accordingly, other implementations are possible. Furthermore, although certain components of the DrMOS dies are depicted, DrMOS dies can include additional circuitry and/or other pin configurations.

In the illustrated embodiment, an input control signal INa is provided to the logic 615a. The logic 615a controls driver signals to the high side driver 613a and the low side driver 614a, which control the high side power MOSFET 611a and low side power MOSFET 612a, respectively. The high side power MOSFET 611a and low side power MOSFET 612a are coupled to a first terminal VSWa of the inductor 608a to form a half bridge circuit of a switching regulator, such as a buck converter. The MOSFETs 612a/612b are switched on and off to control a current provided to the inductor 608a. A second terminal of the inductor 608a electrically connects to an output voltage pin VOUT for a customer circuit board.

With continuing reference to FIG. 7, an input control signal INb is provided to the logic 615b. The logic 615b controls driver signals to the high side driver 613b and the low side driver 614b, which control the high side power MOSFET 611b and low side power MOSFET 612b, respectively. The high side power MOSFET 611b and low side power MOSFET 612b are coupled to a first terminal VSWb of the inductor 608b and are switched on and off to control a current provided to the inductor 608b. A second terminal of the inductor 608b electrically connects to the output voltage pin VOUT.

### Applications

Devices employing the above-described schemes can be implemented into various electronic devices in a wide range of applications including, but not limited to, bus converters, high current distributed power systems, telecom systems, datacom systems, storage systems, and automotive systems. Thus, examples of electronic devices that can be implemented with the power modules herein include, but are not limited to, communication systems, consumer electronic products, electronic test equipment, communication infrastructure, servers, automobiles, etc.

### Conclusion

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. A power module comprising:
a first circuit board having a first side and a second side opposite the first side;
a first semiconductor die attached to the first side of the first circuit board;
an inductor component attached to the second side of the first circuit board, the inductor component having a dielectric body and a first cavity in the dielectric body facing the second side of the first circuit board; and
a second semiconductor die attached to the second side of the first circuit board in the cavity of the dielectric body.

2. The power module of claim 1, wherein the first circuit board includes metallization thermally connecting the second semiconductor die to the first semiconductor die.

3. The power module of claim 2, further comprising a heat sink and/or a cold plate attached to the first semiconductor die, wherein the metallization and the first semiconductor die provide a thermal pathway for heat to transfer from the second semiconductor die to the heat sink and/or the cold plate.

4. The power module of claim 2, wherein the metallization includes a plurality of vias providing a direct thermal connection from the second semiconductor die to the first semiconductor die.

5. The power module of claim 2, wherein the metallization further provides a ground or a power supply connection between the first semiconductor die and the second semiconductor die.

6. The power module of claim 1, further comprising a third semiconductor die attached to the first side of the first circuit board, and a fourth semiconductor die attached to the second side of the first circuit board in the cavity of the dielectric body.

7. The power module of claim 1, further comprising a second circuit board attached to the inductor component opposite the first circuit board, the inductor component including one or more inductors formed through the dielectric body and each having a first terminal electrically connected to the first circuit board and a second terminal electrically connected to the second circuit board.

8. The power module of claim 7, wherein the dielectric body further at least one additional cavity facing the second circuit board, the power module further comprising one or more surface mount components in the at least one additional cavity.

9. The power module of claim 1, wherein the dielectric body includes a ferrite core.

10. The power module of claim 1, wherein the cavity of the dielectric body has a height of less than 1 mm.

11. A power regulation system comprising:
a customer board; and
a power module attached to the customer board, the power module comprising:
a first circuit board having a first side and a second side opposite the first side;
a first semiconductor die attached to the first side of the first circuit board;
an inductor component attached to the second side of the first circuit board, the inductor component having a dielectric body and a first cavity in the dielectric body facing the second side of the first circuit board; and
a second semiconductor die attached to the second side of the first circuit board in the cavity of the dielectric body.

12. The power regulation system of claim 11, further comprising at least one of a heat sink or a cold plate attached to the inductor component opposite the customer board.

13. The power regulation system of claim 11, wherein the first circuit board includes metallization thermally connecting the second semiconductor die to the first semiconductor die.

14. The power regulation system of claim 13, wherein the metallization includes a plurality of vias providing a direct thermal connection from the second semiconductor die to the first semiconductor die.

15. The power regulation system of claim 13, wherein the metallization further provides a ground or a power supply connection between the first semiconductor die and the second semiconductor die.

16. The power regulation system of claim 11, further comprising a third semiconductor die attached to the first side of the first circuit board, and a fourth semiconductor die attached to the second side of the first circuit board in the cavity of the dielectric body.

17. The power regulation system of claim 11, further comprising a second circuit board attached to the inductor component opposite the first circuit board, the inductor component including one or more inductors formed through the dielectric body and each having a first terminal electrically connected to the first circuit board and a second terminal electrically connected to the second circuit board.

18. The power regulation system of claim 17, wherein the dielectric body further at least one additional cavity facing the second circuit board, the power module further comprising one or more surface mount components in the at least one additional cavity.

19. The power regulation system of claim 11, wherein the cavity of the dielectric body has a height of less than 1 mm.

20. A method of assembling a power module, the method comprising:
attaching a first semiconductor die to a first side of a first circuit board;
attaching a second semiconductor die to a second side of the first circuit board opposite the first side; and
attaching an inductor component attached to the second side of the first circuit board, the inductor component having a dielectric body and a first cavity in the dielectric body facing the second side of the first circuit board, the second semiconductor die positioned in the cavity of the dielectric body.
